(19) United States
(12) Patent Application Publication
(10) Pub. No.: US 2024/0273277 A1
(43) Pub. Date: Aug. 15, 2024

(54) METHODS AND APPARATUS FOR SEGMENTATION AND VERIFICATION, ELECTRONIC DEVICE, AND STORAGE MEDIUM

(71) Applicant: S2C Limited, Shanghai (CN)

(72) Inventors: Wan Lu, Shanghai (CN); Jifeng Zhang, Shanghai (CN); Hui Xiao, Shanghai (CN); Zhongwei Shao, Shanghai (CN)

(21) Appl. No.: 18/567,297

(22) PCT Filed: Oct. 27, 2021
(86) PCT No.: PCT/CN2021/126699

§ 371 Date: Dec. 5, 2023

(30) Foreign Application Priority Data
Jun. 1, 2021 (CN) 202110628338.1

(51) Int. Cl. G06F 30/398; G06F 30/34

(52) U.S. Cl. CPC G06F 30/398; G06F 30/34

(57) ABSTRACT

Methods and apparatus for segmentation and verification, an electronic device, and a storage medium, which are applied to the technical field of electronic design automation. The segmentation solution comprises: classifying nodes in a chip design, merging the classified nodes, and segmenting the new merged nodes so as to arrange segmentation boundaries on net provided with trigger driving. The accuracy and efficiency in segmenting and verifying a chip design can be improved by optimizing and adjusting all segmentation boundaries onto net provided with trigger driving.

### TECHNICAL FIELD

The specification relates to the technical field of electronic design automation, in particular to a method, a device, electronic device and a storage medium for segmentation and verification chip design.

### BACKGROUND ART

At present, a chip design is usually segmented into multiple code blocks (that is, partitions), and a prototype verification system (such as multi-FPGA prototype verification system) is composed of multiple verification chips (such as FPGA, field programmable gate array) to verify the chip design.

In the segmentation and verification of chip design, because the time delay of signal transmission between FPGAs is usually much longer than the time delay of signal transmission inside FPGAs, in the partition verification of multi-FPGA prototype system, not only many new problems that did not exist in the original design may be introduced and new solutions need to be adopted to solve these new problems, but also other new problems may exist in the new solutions to solve new problems, such as system performance degradation and verification failing to accurately reflect the performance and function of the original chip design.

Therefore, a new segmentation scheme is urgently needed.

### SUMMARY OF THE INVENTION

In view of this, the embodiment of this specification provides a segmentation and verification method, device, electronic device and storage medium, which can optimize the segmentation boundary position and provide an efficient and reliable segmentation verification scheme for chip design.

The embodiment of the specification provides the following technical scheme: The embodiment of the specification provides a segmentation method, which includes the following steps: classifying nodes in chip design to correspondingly divide each node into: nodes with ffd attributes, nodes with inherited ffd attributes or nodes without ffd attributes: Merging nodes without ffd attributes with nodes with ffd attributes or nodes with inherited ffd attributes according to a preset merging strategy to form a target graph: Segmenting the target graph according to a preset segmentation strategy, so as to set the segmentation boundary on the output line of the node with ffd attribute in the target graph, or set the segmentation boundary on the output line of the node with ffd attribute inherited in the target graph.

The embodiment of the specification also provides a verification method, which includes the following steps: classifying the nodes in the chip design to correspondingly divide each node into nodes with ffd attributes, nodes with inherited ffd attributes or nodes without ffd attributes: Merging nodes without ffd attributes with nodes with ffd attributes or nodes with inherited ffd attributes according to a preset merging strategy to form a target graph: Segmenting the target graph according to a preset segmentation strategy, so as to set the segmentation boundary on the output line of a node with ffd attribute in the target graph, or set the segmentation boundary on the output line of a node with ffd attribute inherited in the target graph: A verification system is adopted to verify the segmentation result, wherein the verification system at least comprises two verification chips.

The embodiment of the specification also provides a segmentation apparatus, which includes:
a classification module is used for classifying the nodes in the chip design so as to correspondingly divide each node into nodes with ffd attributes, nodes with inherited ffd attributes or nodes without ffd attributes;
a merging module, which merges nodes without ffd attributes with nodes with ffd attributes or nodes with inherited ffd attributes according to a preset merging strategy to form a target graph;
a segmentation module is used for segmenting the target graph according to a preset segmentation strategy, so as to set the segmentation boundary on the output line of the node with ffd attribute in the target graph, or set the segmentation boundary on the output line of the node with ffd attribute inherited in the target graph.

The embodiment of the specification also provides a verification apparatus, which includes:
a classification module is used for classifying the nodes in the chip design so as to correspondingly divide each node into nodes with ffd attributes, nodes with inherited ffd attributes or nodes without ffd attributes;
a merging module, which merges nodes without ffd attributes with nodes with ffd attributes or nodes with inherited ffd attributes according to a preset merging strategy to form a target graph;
a segmentation module is used for segmenting the target graph according to a preset segmentation strategy, so as to set the segmentation boundary on the output line of a node with ffd attribute in the target graph, or set the segmentation boundary on the output line of a node with ffd attribute inherited in the target graph;
a verification module is used for verifying the segmentation result by adopting a verification system, wherein the verification system at least comprises two verification chips.

The embodiment of this specification also provides an electronic device for segmentation, including:

At least one processor: And a memory communicatively connected with the at least one processor: Wherein the memory stores instructions executable by the at least one processor, and the instructions are executed by the at least one processor to enable the at least one processor to execute:
Classifying the nodes in the chip design, so as to divide each node into nodes with ffd attributes, nodes with inherited ffd attributes or nodes without ffd attributes;
Merging nodes without ffd attributes with nodes with ffd attributes or nodes with inherited ffd attributes according to a preset merging strategy to form a target graph;
Segmenting the target graph according to a preset segmentation strategy, so as to set the segmentation boundary on the output line of the node with ffd attribute in the target graph, or set the segmentation boundary on the output line of the node with ffd attribute inherited in the target graph.

The embodiment of this specification also provides an electronic device for verification, including:

At least one processor: And a memory communicatively connected with the at least one processor: Wherein the memory stores instructions executable by the at least one processor, and the instructions are executed by the at least one processor to enable the at least one processor to execute:
Classifying the nodes in the chip design, so as to divide each node into nodes with ffd attributes, nodes with inherited ffd attributes or nodes without ffd attributes;
Merging nodes without ffd attributes with nodes with ffd attributes or nodes with inherited ffd attributes according to a preset merging strategy to form a target graph;
Segmenting the target graph according to a preset segmentation strategy, so as to set the segmentation boundary on the output line of a node with ffd attribute in the target graph, or to set the segmentation boundary on the output line of a node with ffd attribute inherited in the target graph:

A verification system is adopted to verify the segmentation result, wherein the verification system at least comprises two verification chips.

The embodiment of the specification also provides a computer storage medium for segmentation, wherein the computer storage medium stores computer executable instructions, and the computer executable instructions are set as follows:
Classifying the nodes in the chip design, so as to divide each node into nodes with ffd attributes, nodes with inherited ffd attributes or nodes without ffd attributes;
Merging nodes without ffd attributes with nodes with ffd attributes or nodes with inherited ffd attributes according to a preset merging strategy to form a target graph;
Segmenting the target graph according to a preset segmentation strategy, so as to set the segmentation boundary on the output line of the node with ffd attribute in the target graph, or set the segmentation boundary on the output line of the node with ffd attribute inherited in the target graph.

The embodiment of the specification also provides a computer storage medium for verification, wherein the computer storage medium stores computer executable instructions, and the computer executable instructions are set as follows:
Classifying the nodes in the chip design, so as to divide each node into nodes with ffd attributes, nodes with inherited ffd attributes or nodes without ffd attributes;
Merging nodes without ffd attributes with nodes with ffd attributes or nodes with inherited ffd attributes according to a preset merging strategy to form a target graph;
Segmenting the target graph according to a preset segmentation strategy, so as to set the segmentation boundary on the output line of a node with ffd attribute in the target graph, or to set the segmentation boundary on the output line of a node with ffd attribute inherited in the target graph:

A verification system is adopted to verify the segmentation result, wherein the verification system at least comprises two verification chips.

Compared with the prior art, the above-mentioned at least one technical scheme adopted in the embodiment of this specification can at least achieve the following beneficial effects:

By adjusting the segmented boundaries, the driving nodes of all the divided wires are all nodes with ffd attributes, such as nodes with ffd attributes and nodes with inherited ffd attributes. Therefore, after the segmentation, not only can the clock signal be prevented from being cut, but also new problems caused by the need to transmit the clock signal among multiple verification chips (such as FPGA) through interconnection nets. Moreover, it can make full use of the time interval between the receiving data and the sending data of the trigger, reduce or even offset the time delay effect of signals transmitted by interconnection nets between multiple verification chips (such as FPGA), and avoid reducing the performance of verification systems (such as multi-FPGA prototype verification systems), which can provide an efficient and reliable segmentation scheme system for chip design.

### BRIEF DESCRIPTION OF THE DRAWINGS

In order to explain the technical scheme of the embodiment of the present disclosure more clearly, the drawings needed in the embodiment will be briefly introduced below. Obviously, the drawings described below are only some embodiments of the present disclosure, and other drawings can be obtained according to these drawings without creative work for ordinary people in the field.

FIG. 1 is a schematic diagram of a multi-FPGA prototype verification system with clock output lines cut in the existing scheme;

FIG. 2 is a schematic diagram showing that the output line of the combinational logic circuit in the prior art is segmented:

FIG. 3 is a schematic time sequence diagram of the corresponding data before and after the output line of the combinational logic circuit is divided in the existing scheme:

FIG. 4 is a schematic diagram of the existing scheme in which the output line of the combinational logic circuit is cut out and inserted into TDM:

FIG. 5 is a time sequence diagram of the corresponding data before and after TDM is inserted into the output line of the combinational logic circuit in the existing scheme;

FIG. 6 is a schematic diagram showing that the segmentation boundary is adjusted in a segmentation method provided by the embodiment of this specification:

FIG. 7 is a time sequence diagram of corresponding data before and after the segmentation boundary is adjusted in a segmentation method provided by an embodiment of this specification;

FIG. 8 is a schematic diagram in which the division boundary is adjusted and inserted into TDM in a division method provided by the embodiment of this specification:

FIG. 9 is a time sequence diagram of corresponding data before and after the division boundary is adjusted and inserted into TDM in a division method provided by an embodiment of this specification:

FIG. 10 is a flowchart of a segmentation method provided by an embodiment of this specification:

FIG. 11 is a flowchart of a segmentation method provided by an embodiment of this specification:

FIG. 12 is a schematic structural diagram of a dividing device provided by an embodiment of this specification:

FIG. 13 is a schematic structural diagram of an electronic device for segmentation provided by the embodiment of this specification:

FIG. 14 is a flowchart of a verification method provided by an embodiment of this specification:

FIG. 15 is a schematic structural diagram of a verification apparatus provided by an embodiment of this specification.

### DETAILED DESCRIPTION

The embodiments of the present application will be described in detail with the drawings.

The following describes the implementation of the application through specific embodiments, and those skilled in the art can easily understand other advantages and effects of the application from the contents disclosed in this specification. Obviously, the described embodiment is only a part of the embodiment of this application, not the whole embodiment. This application can also be implemented or applied through different specific embodiments, and the details in this specification can be modified or changed based on different viewpoints and applications without departing from the spirit of this application. It should be noted that the following embodiments and features in the embodiments can be combined with each other without conflict. Based on the embodiments in this application, all other embodiments obtained by ordinary technicians in this field without creative work belong to the protection scope of this application.

It is noted that various aspects of the embodiments within the scope of the appended claims are described below. It should be obvious that the aspects described herein can be embodied in a wide variety of forms, and any specific structure and/or function described herein is merely illustrative. Based on this application, those skilled in the art should understand that one aspect described herein can be implemented independently of any other aspect, and two or more of these aspects can be combined in various ways. For example, devices and/or practice methods may be implemented using any number and aspects set forth herein. In addition, the apparatus and/or the method may be implemented using other structures and/or functionalities than one or more of the aspects set forth herein.

It should also be noted that the diagrams provided in the following examples only illustrate the basic concept of this application in a schematic way, and only the components related to this application are shown in the diagrams, instead of being drawn according to the number, shape and size of components in actual implementation. In actual implementation, the types, numbers and proportions of components can be changed at will, and the layout of components may be more complicated.

In addition, in the following description, specific details are provided to facilitate a thorough understanding of the examples. However, it will be understood by those skilled in the art that the described aspects may be practiced without these specific details. The terms “first”, “second” and so on are only used for descriptive purposes, and cannot be understood as indicating or implying relative importance or implicitly indicating the number of indicated technical features. Thus, features defined by “first”, “second” and other descriptions may include one or more of these features explicitly or implicitly. In the description of this specification, unless otherwise specified, “plural” means two or more.

In the current segmentation verification, the following are three common scenarios that partition (that is, verification after segmentation) leads to new problems, and the corresponding solutions are adopted in the multi FPGA prototype verification system to solve the new problems.

### Scenario 1: The Output Line of the Clock Signal is Cut.

When the output line of the clock signal is cut, that is, the same clock signal used to process data in the original design is segmented into different partitions, such as clock signal CLK, which needs to be used among multiple FPGAs after being segmented. Since the transmission delay of the interconnection net between FPGAs is much longer than the transmission delay inside FPGAs, there will be clock phase deviation in different FPGAs, such as the clock signal CLK between the receiving end (such as FPGA2) and the sending end (such as FPGA1) is not in phase. If non in-phase clock signals are used to process data, the processing results will be distorted, such as data asynchronization, data result distortion and errors.

In order to avoid clock phase shift, as shown in FIG. 1, in the existing scheme, the clock signal CLK can be copied to each FPGA (as shown in the dotted box in the figure), that is, the clock signal CLK can be copied to FPGA1 and FPGA2 respectively by using the internal resources of FPGA, thus ensuring the accurate segmentation verification result by sacrificing the physical resources of FPGA, that is, exchanging space for accuracy.

### Scenario 2: The Output Line of Combinational Logic is Cut.

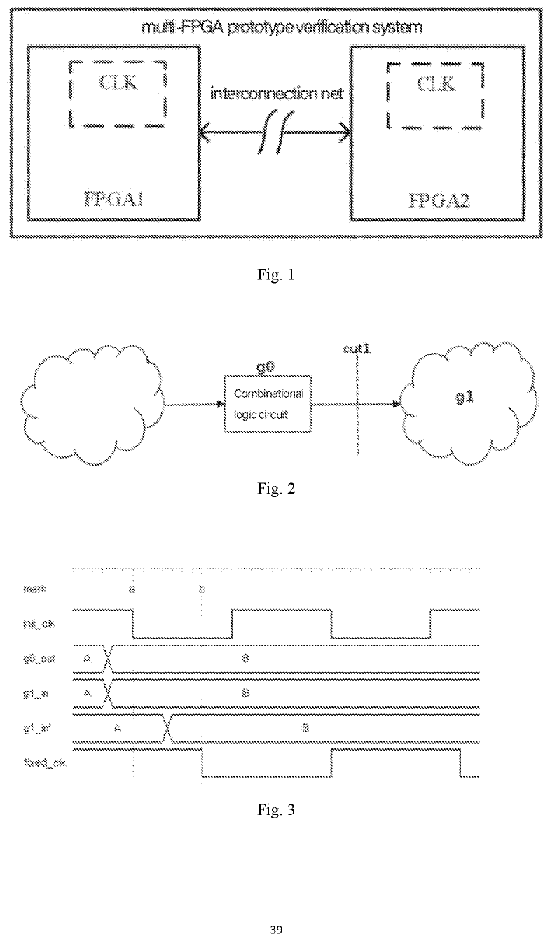

As shown in FIG. 2 to FIG. 3, wherein FIG. 2 is a schematic diagram of cutting the output line of the combinational logic circuit (cut1 as shown in the figure), and FIG. 3 is a timing diagram of output data of g0 and received data of g1 before and after cutting.

When it is not cut, the data received by g1 is shown as g1_in, and g1 can immediately receive the data from g0. If the data of g1 is selected for processing at time a, that is, at the falling edge of the clock init_clk, there will be no processing error. However, when the output line of combinational logic circuit g0 is cut, due to the influence of interconnection between FPGA, such as the influence of time delay, there will be a time difference between the data received by g1 and the data output by g0 as shown in g1_in′. At this time, if the data is still acquired at the falling edge of the original clock (such as time a marked by mark), the acquired data will still be old data A, so a data processing error will occur.

In order to solve this problem, we can reduce the clock frequency, such as using the low-frequency clock fixed_clk shown in the figure, and then use the falling edge of the low-frequency clock signal fixed_clk to collect the correct data after g1 stably receives the new data of g0, that is, by reducing the clock frequency, we can delay the time of receiving data to obtain the correct data, that is, sacrifice time for accuracy.

### Scenario 3: Time-Division Multiplexing (TDM) Module is Inserted at the Cutting Place.

In the multi-FPGA prototype verification system, the interconnection of multiple FPGAs often leads to a surge in the demand for IO (Input/Output), so TDM can be used to solve the IO bottleneck.

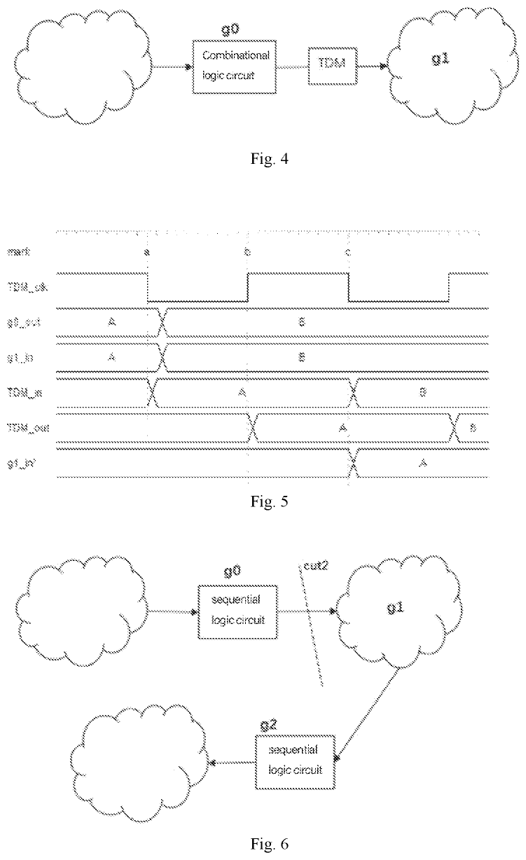

As shown in FIG. 4 to FIG. 5, in which FIG. 4 is a schematic diagram of inserting TDM between g0 and g1 after cutting the output line of combinational logic circuit, and FIG. 5 is a timing diagram of g0 outputting data, TDM receiving and transmitting data and g1 receiving data before and after cutting.

When the output line of the combinational logic circuit g0 is not cut, the data received by g1 is shown as g1_in, and g1 can immediately receive the data from g0 without generating an error. However, when the output line of the combinational logic circuit g0 is cut and TDM is inserted between partitions, in which TDM collects data on the falling edge of the clock pulse and sends data on the rising edge, under the action of the clock TDM_clk (assuming that the frequency of the clock TDM_clk is the same as that of the original design clock), if the data output by g0 changes from A to B after the falling edge of TDM_clk, then the input TDM_in of TDM is data A, However, the output TDM_out is still the old data A, which will cause the data received by g1 to be still the old data A, as shown by g1_in′, and thus a processing error will occur.

Therefore, in the multi FPGA prototype verification system, it is still necessary to reduce the sampling clock frequency of TDM to avoid the risk of transmitting wrong values, that is, to sacrifice time for accuracy.

However, when the sampling clock frequency of TDM is reduced to a certain value, it may cause it to work abnormally, and even the verification system will not work normally.

To sum up, although the existing schemes (such as multi FPGA prototype verification system) can solve the new problems in segmentation verification to some extent by taking corresponding measures, such as sacrificing the space of FPGA, such as reducing the clock frequency (that is, sacrificing time), these solutions are all compromise schemes that need to sacrifice the system performance: Moreover, these compromise solutions are only abstract models that consider a single delay factor when there are multiple FPGA, and the actual segmentation verification may be affected by more than one delay factor, that is, not all the new problems actually appear may be caused by the delay factor, so these existing compromise solutions cannot provide efficient and reliable solutions for the segmentation verification of chip design.

Based on this, after in-depth research and analysis of a large number of segmented data, the inventor proposed a new segmentation scheme for chip design segmentation: optimizing and adjusting the segmentation boundary, that is, using the flip-flop state to change only at the moment of the rising or falling edge of the clock pulse, and the output time of the flip-flop can be controlled, so that the cutting boundary can be placed on the output line of the node with ffd attribute in the segmentation. That is to say, all cutting edges are located on the output lines with ffd attribute nodes, which can not only avoid the situation that the output lines of the clock are cut, but also make use of the time interval between the received data and the sent data of the flip-flop, so that there is a stable time difference between the data received by the partitioned receiving end and the data sent by the sending end, such as the time interval between the data received by the receiving end and the data sent by the rising edge through the sequential logic circuit. It can counteract the influence caused by propagation delay, so that when the output line of sequential logic circuit is cut, the influence caused by the signal transmission delay of interconnection nets between FPGAs is reduced, and the operation possibility of reducing the performance of multi FPGA prototype verification system is greatly reduced, even without reducing the performance of multi FPGA prototype verification system, which can provide an efficient and reliable segmentation scheme for chip design.

In practice, a node with ffd attribute (i.e. with ffd attribute) can be a node with ffd attribute itself or a node that obtains ffd attribute through inheritance, and ffd attribute can be a trigger-driven feature.

It should be noted that inheritance can obtain the ffd attribute for the node from its related driving node, that is, the node can directly or indirectly inherit the ffd attribute, for example, the node can obtain the ffd attribute through direct inheritance, for example, the driving node of the node has the ffd attribute, so that the driven node can directly inherit the ffd attribute through the driving relationship, for example, the node obtains the ffd attribute through indirect inheritance, for example, the driving node of the node obtains the ffd attribute through inheritance.

In order to understand the segmentation idea provided in this specification, the following is a schematic illustration of a node with ffd attribute, in which the example description of a node that inherits ffd attribute can be similar to the following, and the description will not be expanded.

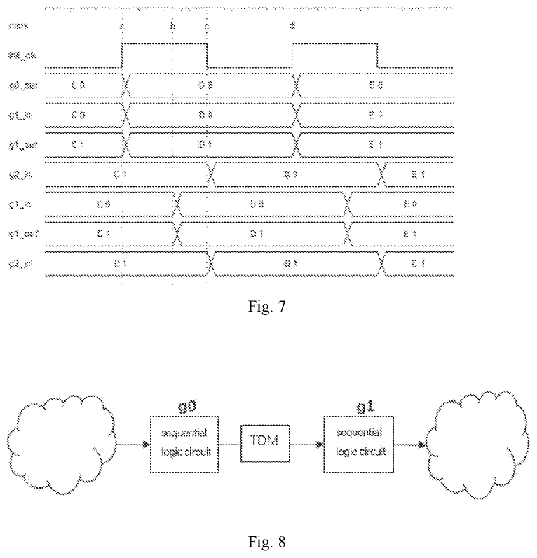

Example 1, as shown in FIG. 6, the boundary cut2 can be adjusted to the output line of sequential logic circuit g0, and accordingly, the data of the receiving end and the ending end on both sides of the boundary before and after segmentation can be shown in FIG. 7.

Before cutting, the sequential logic circuit can send data under the action of the clock init_clk, such as the rising edge of the clock and the falling edge of the clock, and can correctly receive and send data, such as the data sent by the sequential logic circuit g0 (such as data C0, D0, E0, etc., see g0_out in the figure), and g1 normally receives the data (see g1_in the figure). Accordingly, g1 is processed to obtain corresponding output data (such as data C1, D1, E1, etc., as shown in the diagram of g1_out in the figure), and the sequential logic circuit g2 can receive the data output by g1 in time (such as data C1, D1, E1, etc., as shown in the diagram of g2_in in the figure).

When the cutting boundary is adjusted to the output line of a node with ffd attribute, such as the boundary cut2 shown in the figure, the signals on both sides of the boundary may be affected by the transmission delay of the interconnection net after being transmitted through the interconnection net between FPGA, for example, and the input data after g1 cutting (such as C0, D0, E0, etc., see g1_in′ in the figure) and the input data before cutting (such as C0, D0, E0, etc.) are different. There is a fixed time difference (for example, the time difference between mark a and Mark b in the figure), and the time sequence logic circuit g2 reads the data under the action of the clock signal, that is, g2 only reads the data at the falling edge of the clock signal init_clk, which can offset the influence caused by this time delay, so that the data of g2 can remain the same before and after cutting, that is, the time sequence diagram of g2 receiving data has not changed (see g2_in and g2_in′ in the figure), and without generating processing errors.

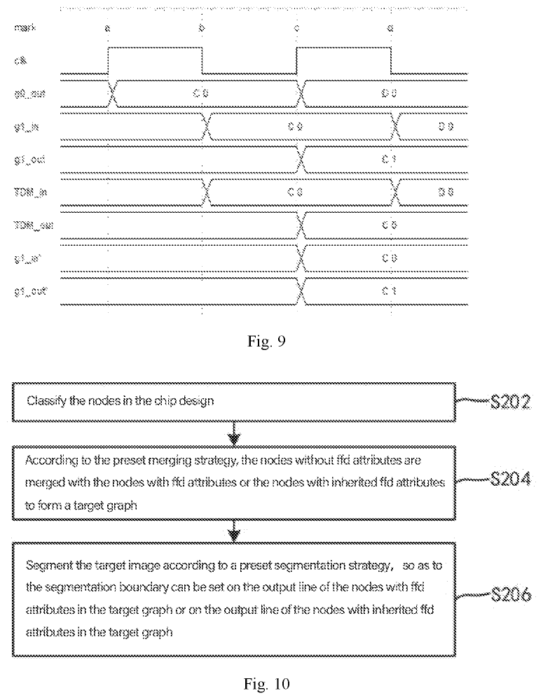

Example 2, as shown in FIG. 8, the dividing boundary can be adjusted between two sequential logic circuits, for example, the boundary can be adjusted to the output line of sequential logic circuit g0, and TDM can be inserted there to solve the IO requirements in verification: Accordingly, the data of the receiving end and the sending end on both sides of the boundary before and after segmentation can be shown in FIG. 9.

Assuming that the clock frequency of the TDM sampling is consistent with the originally designed clock frequency clk, there can be a stable time difference between the data received by the receiving end and the data sent by the sending end of the TDM (such as the time difference between mark b and Mark c in the figure). When the data of the receiving end g1 passes through the time interval of receiving data at the falling edge and sending data at the rising edge of the sequential logic circuit, for example, g1 reads the data at the falling edge of the clock signal clk. The influence caused by this time delay can be offset, so that the output data of g1 can still be the same before and after cutting, that is, the timing diagram of g1 output data has not changed (see the diagram of g1_out and g1_out′ in the figure), and without generating processing errors.

It should be noted that the segmentation method and/or the verification method provided by the embodiment of this specification can be executed by the terminal and/or the server, and any step in the method can also be executed by the terminal and/or the server, which is not limited here.

In addition, the terminal may include any user terminal such as a computer, a tablet computer, a mobile intelligent device, etc., and the server may include an application server such as a server or a server cluster, where the terminal and the server do not limit the embodiments of this specification.

Hereinafter, the technical scheme provided by each embodiment of this specification will be described in detail with the drawings.

As shown in FIG. 10, the embodiment of this specification provides a segmentation method for chip design segmentation verification, which may include the following:

Step S202: Classify the nodes in the chip design.

In practice, all nodes in chip design can be divided into the following three types: nodes with ffd attributes, nodes with inherited ffd attributes, and nodes without ffd attributes.

A node with ffd attribute can refer to the module corresponding to the node in the actual chip design, which meets the following two conditions: the module contains a trigger device, and all the output ports of the module trace back inside the module, and the trigger device, VCC (voltage current condenser) or GND (Ground, wire ground end) must be met.

The node that inherits the ffd attribute can refer to the module that the node corresponds to in the actual design. The module obtains the ffd attribute by inheriting the ffd attribute of its driving node, such as being driven by a node with the ffd attribute, such as being driven by a node that inherits the ffd attribute.

A node without ffd attribute can refer to the module corresponding to the node in actual design. The module itself does not have ffd attribute, nor can it inherit ffd attribute from its driving node.

It should be noted that a chip design is usually composed of several modules, and in order to facilitate the segmentation, the modules in the chip design are usually converted into nodes, that is, a node can correspond to a module, where the module can be a module in the chip design or a new module formed by encapsulating some statements in a module in the chip design.

Step S204: According to the preset merging strategy, the nodes without ffd attributes are merged with the nodes with ffd attributes or the nodes with inherited ffd attributes to form a target graph.

In practice, the preset merging strategy can be preset and adjusted according to the actual application needs. In the merging process, the nearest node with ffd attribute/node that can inherit ffd attribute can be found along the direction of its output signal transmission, and all the nodes along the way can be merged together, which can ensure that the merged nodes are nodes with ffd attribute, that is, nodes with ffd attribute or nodes that can inherit ffd attribute.

Step S206: Segment the target image according to a preset segmentation strategy.

After step S204, that is, after merging the nodes without ffd attributes, only the above two types of nodes are left in the obtained target graph, that is, the nodes with ffd attributes and the nodes with inherited ffd attributes. Therefore, when segmenting the target graph, the segmentation boundary can be set on the output line of the nodes with ffd attributes in the target graph or on the output line of the nodes with inherited ffd attributes in the target graph.

It should be noted that the preset segmentation strategy can be preset according to the actual application needs, such as the segmentation strategy with weight constraints, such as the segmentation strategy with multiple partitions according to the resources of the verification system, and so on, which will not be enumerated here.

Through step S202 to step S206, in the process of segmenting and verifying the original chip design, the segmentation boundary can be located on the output line of the node with ffd attribute or on the output line of the node with inherited ffd attribute, that is, the segmentation boundary is adjusted to the output line of the node with ffd attribute. Therefore, this segmentation scheme can not only avoid the new problem that the clock signal needs to be transmitted between multiple verification chips (such as FPGA) because the output line of the clock is cut, but also make full use of the time interval between receiving data and sending data of the flip-flop, which can reduce or even offset the delay effect of signal transmission between multiple verification chips (such as FPGA), without reducing the performance of verification systems (such as multi-FPGA prototype verification systems), and provide an efficient and reliable segmentation scheme for chip design.

In some embodiments, the design file corresponding to the chip design designed by the user can be preprocessed to obtain the data information of all nodes corresponding to the chip design, which is convenient for node classification.

In practice, the design file of the chip design can be read into the memory, so that the design file can be generated into a corresponding graph which can be used for segmentation processing by means of syntax analysis, wherein each node of the graph has corresponding classification information, and the classification information can include node attribute information, and the node attribute information can include information for representing whether the node has ffd attribute, so that all nodes can be classified quickly and accurately according to the node attribute information in the node classification information, and the processing efficiency can be improved.

It should be noted that the attribute with ffd can be the aforementioned attribute with ffd and the attribute with ffd obtained by inheritance, and no distinction is made here.

In some embodiments, some design information can be reflected in the classification information according to the actual application needs, which can improve the accuracy and efficiency of classifying nodes by using the classification information.

In practice, the classification information can also include at least one of the following information: the original design module name information corresponding to each node, the network connection information between nodes and the preset division standard information:

In practice, the node attribute information may also include resource occupation information used to characterize the number of resources occupied by each node.

Through the original design module name information corresponding to each node, the corresponding node can be quickly determined, which can improve the processing efficiency: Through the network connection information between nodes, the relationship between nodes can be quickly determined, which can improve the processing efficiency: By presetting the division standard information (that is, the division standard information specified by the user in advance), the processing can be quickly carried out according to the preset requirements, and the processing efficiency can be improved: According to the number of resources occupied by each node, it can be segmented quickly and accurately, which ensures that the segmentation result can meet the resources of each verification chip in the verification system and improve the processing efficiency.

In some embodiments, the design file can be a netlist, and then the classification information of each node can be quickly generated according to the netlist, thus improving the processing efficiency.

In some embodiments, the segmentation boundary can be adjusted to the output line of the node with ffd attribute as much as possible to improve the efficiency of segmentation and subsequent verification.

In practice, a segmentation strategy based on weight can be adopted for segmentation. At this time, before segmentation, the weights of output lines of nodes with ffd attributes and/or the weights of net between nodes inheriting ffd attributes and their driving nodes can be adjusted.

For example, when the nodes with small weights are preferentially segmented according to the size of weights, a higher weight value can be given to the target connection line (target net, which can be referred to as maybe_net for convenience of schematic explanation) in adjusting the weight of the connection line (net) between nodes, wherein the driving node of maybe_net can be the node that obtains the ffd attribute through inheritance.

It should be noted that the driving node of maybe_net can be a node that obtains the ffd attribute through inheritance, that is, the driving node can obtain the ffd attribute through direct inheritance, indirect inheritance, etc., wherein the indirect inheritance can be that the driving node of the driving node is a node that obtains the ffd attribute through inheritance.

In some embodiments, after merging nodes without ffd attributes, the weights of all the lines in the merged target graph can be updated, and the weights of lines driven by nodes with ffd attributes are given a small value, and the weights of links driven by nodes that can inherit ffd attributes are given a higher value, so that the lines with smaller weight values can be preferentially segmented during segmentation.

In some embodiments, the depth of indirect inheritance can be constrained according to the actual application needs. For example, the depth of indirect inheritance is limited to no more than 3 layers, that is, the node with ffd attribute is inherited, and the driving node of its driving node needs to be a node with ffd attribute, which can improve the processing efficiency of segmentation and subsequent verification.

It should be noted that indirectly inherited nodes whose depth does not meet the constraint conditions can also be marked as nodes without ffd attribute, which is convenient for subsequent processing.

In some embodiments, after the target graph is segmented according to a preset segmentation strategy, the segmented result can be checked to adjust the segmented boundary to the output line of the node with ffd attribute as much as possible, so as to improve the reliability of the segmented result and the processing efficiency of segmentation and subsequent verification.

In practice, the segmentation result can be checked to see whether the segmentation boundary cuts the aforementioned maybe_net (that is, the target connection line). If no maybe_net is cut, it indicates that the segmentation boundary is located on the output line of the node with ffd attribute.

In some embodiments, when it is determined that the segmentation boundary cuts maybe_net, it can be further determined whether the first driving node is the node that actually obtains the ffd attribute, wherein the first driving node is the driving node of the target connection line.

In practice, when the driving node (i.e., the first driving node) of may_net (i.e., the target connection) is the node that actually obtains the ffd attribute, it shows that may_net can obtain the ffd attribute by inheriting the ffd attribute of its driving node, otherwise, may_net will not be able to obtain the ffd attribute by inheritance.

In some embodiments, it can be determined whether the target node really obtains the ffd attribute by going deep into the connection line relationship between the first driving node and other nodes.

In practice, it can be determined whether the target node really obtains the ffd attribute through the following steps:

Determining whether a connection line between a first driving node and a second driving node is cut, wherein the second driving node is the driving node of the connection line:

If yes, it is determined that the first driving node does not belong to the node that really obtains the ffd attribute.

It should be noted that the first driving node and the second driving node may belong to different verification partitions in the verification due to the cutting of the certain connection line, and at this time, the certain connection line may be affected by the transmission of interconnection nets between different verification partitions, so that the first driving node can be determined as a node that cannot really obtain the ffd attribute, avoiding the unknown influence caused by the cutting of the certain connection line, and improving the accuracy and efficiency of the segmentation and subsequent verification.

In some embodiments, after it is determined that the first driving node does not belong to the node that has truly acquired the ffd attribute, the first driving node and the second driving node can be merged, so as to divide the first driving node and the second driving node into the same verification partition (such as a verification chip, such as an FPGA), which can improve the accuracy and efficiency of segmentation and subsequent verification.

In some embodiments, in the process of merging the first driving node and the second driving node, it can be further determined whether the merging of the first driving node and the second driving node generates a new maybe_net (target connection line), so as to improve the processing accuracy and efficiency of segmentation and subsequent verification.

It should be noted that when a new may_net is generated, corresponding measures can be taken for the new may_net.

For example, to determine whether the driving node of the new maybe_net really obtains the ffd attribute, please refer to the previously explained embodiment for details.

In some embodiments, when it is determined that a new maybe_net is generated, prompt information can be output, and the new maybe_net is prompted to belong to an illegal connection through the prompt information, so that users can know the prompt content and make processing decisions.

In some embodiments, before segmenting the target graph, all nodes can be clustered, that is, the nodes in the target graph are clustered according to a preset clustering strategy, which is beneficial to reducing the order of magnitude of segmentation and improving the accuracy and efficiency of segmentation and subsequent verification.

It should be noted that the preset clustering strategy can be preset and adjusted according to the actual application requirements, such as clustering according to the driving relationship, such as clustering according to the resources of the verification chip, and so on, which is not limited here.

In some embodiments, after the initial segmentation based on the aforementioned embodiments, the segmentation results can be further refined to obtain better segmentation results, which is conducive to improving the accuracy and efficiency of subsequent verification.

In practice, the steps of further refining the segmentation results can include: according to the preset adjustment strategy, trying to move some nodes in one partition into another partition, such as trying to adjust some nodes initially allocated to the first FPGA for partition verification to another FPGA, and determining whether the adjustment can reduce the number of cut nets and make the cut driving nodes of the net have ffd attributes, etc. If it meets the optimizing and adjusting requirements, adjusting, that is, moving the nodes to the target FPGA.

It should be noted that the preset adjustment strategy can be preset and adjusted according to the actual application needs, such as adjusting adjacent nodes segmented into different partitions to the same FPGA according to the driving relationship, such as adjusting different nodes divided into different partitions and needing to use the resources of the FPGA to the same FPGA according to the resource situation of the FPGA, and so on, which are not listed here.

In some embodiments, a refinement operation can be performed on the clustered nodes.

In practice, the clustered nodes can be restored, and several restored nodes can be tried to be adjusted to another partition according to the preset adjustment strategy, so as to reduce the number of cut lines and make the drive nodes of the cut lines have ffd attributes, and obtain better segmentation results, which is beneficial to improving the accuracy and efficiency of subsequent verification.

In order to facilitate the understanding of the segmentation scheme provided in this specification, an example is given below for schematic explanation.

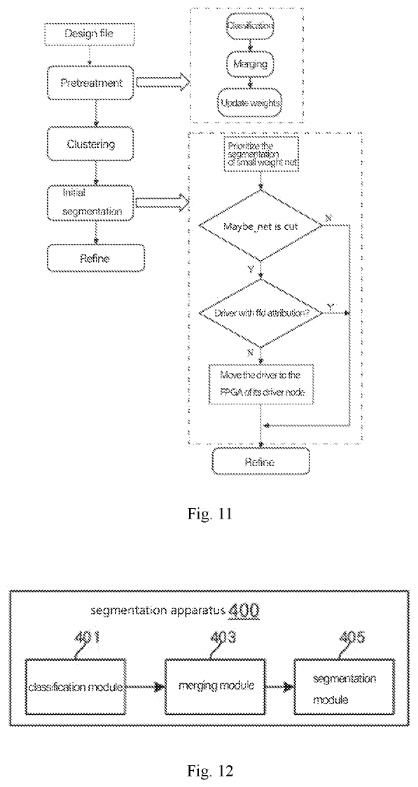

As shown in FIG. 11, the segmentation method may include:

1. Read in the user's design and perform syntax analysis, and read in the user-defined grouping information:

After reading, four parts of information are generated: node information (including the number of resources occupied by each node and whether the node has ffd attribute), original design module name information corresponding to each node, network connection information between nodes, and pre-specified division standard information:

2. Pretreatment stage:

(1) Classification: all nodes are divided into three categories: nodes with ffd attributes, which can be inherited, and nodes without ffd attributes (that is, nodes without ffd attributes);

In practice, after the classification is completed, some connection linns driven by nodes without ffd attributes can be deleted according to the adjustment needs, so as to reduce the number of net driven by nodes without ffd attributes in the subsequent segmented target graph:

(2) Merging: according to the merging rules, the nodes that can't inherit the ffd attribute are merged with the first two types of nodes, that is, the nodes that can't obtain the ffd attribute can find the nearest node with the ffd attribute/the node that can inherit the ffd attribute along the transmission direction of their output signals, and all the nodes along the way are merged together to ensure that the merged nodes have the ffd attribute, that is, only the nodes with the ffd attribute are left after merging.

(3) Update weights: update the weights of all the net (net). For the driving node, it is a net that can inherit the ffd attribute (for convenience of explanation, this net can be called maybe_net below), and give this net a larger weight value, and/or give the net driven by nodes with ffd attribute a smaller weight value. The larger weight value can be the same value (for example, set as the maximum weight value) or different weight values.

3. Clustering: partially merging the nodes with updated weights can reduce the order of magnitude of segmentation:

4. Initial segmentation:
(1) Prioritize the segmentation of small weight values during the segmentation process;
(2) After the segmentation is completed, check whether maybe_net is cut, if not, directly enter the refinement process, otherwise enter the next step;
(3) Determine whether the driving node of maybe_net can really get the ffd attribute (if a net between this node and its driving node is cut, it can't get the ffd attribute), if it can, it will directly enter the refinement process, otherwise it will enter the next step;
(4) Try to move the node of this may_net to the FPGA of the driving node of this node, so that it can obtain the ffd attribute. If this movement does not produce a new may_net, it will directly enter the refinement process: otherwise, enter the refinement process after reporting illegal net:

5. Refine:

Restore the nodes merged in the clustering process. In the process of restoration, try to move the restored node to another FPGA. If the number of cutting net can be reduced and the driving node of the net has ffd attribute, move the node.

Based on the same inventive concept, the embodiment of the specification also provides a device, an electronic device and a computer storage medium corresponding to the segmentation method.

As shown in FIG. 12, the embodiment of this specification provides a segmentation apparatus 400, which may include a classification module 401, which classifies the nodes in the chip design to correspondingly divide each node into nodes with ffd attributes, nodes with inherited ffd attributes or nodes without ffd attributes: A merging module 403, which merges nodes without ffd attributes with nodes with ffd attributes or nodes with inherited ffd attributes according to a preset merging strategy to form a target graph: The segmentation module 405 is configured to segment the target graph according to a preset segmentation strategy, so as to set the segmentation boundary on the output line of the node with ffd attribute in the target graph, or set the segmentation boundary on the output line of the node with ffd attribute inherited in the target graph.

Optionally, the segmentation apparatus 400 may further include:

The node module (not shown in the figure for simplicity and understanding) reads the design file corresponding to the chip design before classifying the nodes in the chip design, and generates classification information corresponding to each node according to the design file, wherein the classification information includes attribute information indicating whether the nodes have ffd attributes, and classifies the nodes in the chip design, including: classifying the nodes in the chip design according to the classification information.

Optionally, the classification information also includes at least one of the following information: original design module name information corresponding to each node, network connection information between nodes and preset division standard information:

And/or the node attribute information further includes resource occupation information representing the number of resources occupied by each node.

Optionally, the preset segmentation strategy includes: a segmentation strategy for segmentation by weight:

The segmentation apparatus 400 may further include:

The updating module (not shown in the figure for simplicity and understanding) adjusts the weight of the target connection line according to the preset weight adjustment strategy, wherein the driving node of the target connection line belongs to the node with ffd attribute or the node with inherited ffd attribute.

Optionally, the segmentation apparatus 400 may further include:

An inspection module (not shown in the figure for simplicity and understanding), after segmenting the target graph according to a preset segmentation strategy, checks the segmentation result to determine whether the segmentation boundary cuts the target connection line.

Optionally, the segmentation apparatus 400 may further include:

A determining module (not shown in the figure for simplicity and understanding), which determines whether the first driving node is the node that really obtains the ffd attribute when determining that the segmentation boundary cuts the target connection line, wherein the first driving node is the driving node of the target connection line.

Optionally, determining whether the first driving node is the node that truly obtains the ffd attribute includes determining whether a connection line between the first driving node and a second driving node is cut, wherein the second driving node is the driving node of the first driving node: If yes, it is determined that the first driving node does not belong to the node that really obtains the ffd attribute.

Optionally, the segmentation apparatus 400 may further include:

A dividing module (not shown in the figure for simplicity and understanding), which merges the first driving node with the second driving node after determining that the first driving node does not belong to the node that truly obtains the ffd attribute, so as to divide the first driving node and the second driving node into the same verification chip.

Optionally, the segmentation apparatus 400 may further include:

A determining module (not shown in the figure for simplicity and understanding of illustration) determines whether a new target connection line is generated by merging the first driving node and the second driving node.

Optionally, the segmentation apparatus 400 may further include:

A prompt module (not shown in the figure for simplicity and understanding) outputs prompt information when it is determined that a new target connection is generated, and the prompt information is used to characterize that the new target connection belongs to an illegal connection line.

Optionally, the segmentation apparatus 400 may further include:

The clustering module (not shown in the figure for simplicity and understanding) clusters the nodes in the target graph according to a preset clustering strategy before segmenting the target graph.

Optionally, the segmentation apparatus 400 may further include:

The restoration module (not shown in the figure for simplicity and understanding) restores the clustered nodes and adjusts the restored nodes to another partition, so as to reduce the number of cut net and make the drive nodes of the cut net have ffd attributes.

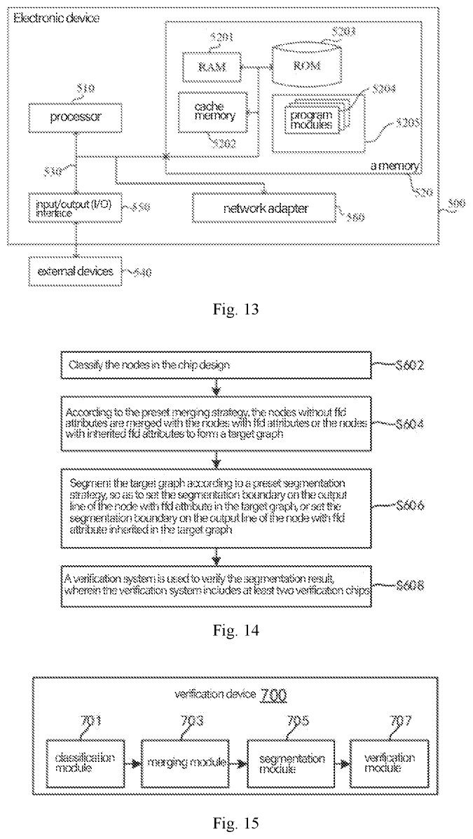

Based on the same inventive concept, as shown in FIG. 13, the embodiment of this specification provides an electronic device for segmentation, and the structure of the electronic device 500 is shown in the figure, so as to realize the corresponding scheme of any of the aforementioned embodiments. The electronic device 500 is only an example, and the function and application scope of the embodiment of the present invention should not be limited.

As shown in FIG. 13, the electronic device 500 may include at least one processor 510; And a memory 520 communicatively connected with the at least one processor; Wherein, the memory 520 has instructions executable by the at least one processor 510, and the instructions are executed by the at least one processor 510, so that the at least one processor 510 can execute the segmentation method described in any embodiment provided in this specification, or the flow of several steps in the segmentation method.

It should be noted that the electronic device 500 can be represented in the form of a general-purpose computing device, for example, it can be a server device.

In practice, the components of the electronic device 500 may include, but are not limited to, the above-mentioned at least one processor 510, the above-mentioned at least one memory 520, and a bus 530 connecting different system components (including the memory 520 and the processor 510), wherein the bus 530 may include a data bus, an address bus and a control bus.

In practice, the memory 520 may include volatile memory, such as random access memory (RAM)5201 and/or cache memory 5202, and may further include read-only memory (ROM)5203.

The memory 520 may also include a program tool 5205 with a set of (at least one) program modules 5204, such program modules 5204 include, but are not limited to, an operating system, one or more application programs, other program modules and program data, and each or some combination of these examples may include the implementation of a network environment.

The processor 510 executes various functional applications and data processing by running computer programs stored in the memory 520.

The electronic device 500 may also communicate with one or more external devices 540 (e.g., keyboard, pointing device, etc.). This communication may be through an input/output (I/O) interface 550. Moreover, the electronic device 500 can also communicate with one or more networks (e.g., local area network (LAN), wide area network (WAN) and/or public network, such as the Internet) through the network adapter 560, which communicates with other modules in the electronic device 500 through the bus 530. It should be understood that although not shown in the figure, other hardware and/or software modules can be used in conjunction with the electronic device 500, including but not limited to microcode, device drivers, redundant processors, external disk drive arrays, RAID (Disk Array) systems, tape drives, data backup storage systems, and the like.

It should be noted that although several units/modules or sub-units/modules of electronic equipment are mentioned in the above detailed description, this division is only exemplary and not mandatory. Actually, according to the embodiment of the present application, the features and functions of two or more units/modules described above can be embodied in one unit/module. On the contrary, the features and functions of one unit/module described above can be further divided and embodied by multiple units/modules.

Based on the same inventive concept, the embodiment of this specification provides a computer storage medium for segmentation, which stores computer executable instructions, and the computer executable instructions are set as: the segmentation method described in any embodiment of this specification, or the flow of several steps in the segmentation method.

It should be noted that the computer storage medium may include, but is not limited to, a portable disk, a hard disk, a random access memory, a read-only memory, an erasable programmable read-only memory, an optical storage device, a magnetic storage device or any suitable combination of the above.

In a possible embodiment, the present invention can also provide the realization of data processing in the form of a program product, which includes program code, and when the program product is run on a terminal device, the program code is used to make the terminal device perform several steps of the method described in any of the preceding embodiments.

Among them, the program code for executing the present invention can be written in any combination of one or more programming languages, which can be completely executed on the user equipment, partially executed on the user equipment, executed as an independent software package, partially executed on the user equipment, partially executed on the remote equipment or completely executed on the remote equipment.

Based on the same inventive concept, the embodiment of this specification provides a verification method to verify the segmentation result corresponding to the chip design by using a multi-chip prototype verification system.

As shown in FIG. 14, the embodiment of this specification provides a verification method, which may include:
Step S602: classify the nodes in the chip design, so as to correspondingly divide each node into: nodes with ffd attributes, nodes with inherited ffd attributes or nodes without ffd attributes;
Step S604: According to the preset merging strategy, the nodes without ffd attributes are merged with the nodes with ffd attributes or the nodes with inherited ffd attributes to form a target graph;
Step S606: Segment the target graph according to a preset segmentation strategy, so as to set the segmentation boundary on the output line of the node with ffd attribute in the target graph, or set the segmentation boundary on the output line of the node with ffd attribute inherited in the target graph;
Step S608: A verification system is used to verify the segmentation result, wherein the verification system comprises at least two verification chips.

Through the above steps S602-S608, it can be realized that all the driving nodes of the segmented net are nodes with ffd attributes, that is, all the segmented net are driven by triggers, which effectively reduces the influence of interconnection among multiple verification chips after segmentation, obviously improves the running speed of the verification system, and ensures the correctness and efficiency of the split verification of chip design.

It should be noted that the steps S602-S606 in the verification method can refer to the related steps S202-S206 in the segmentation method, and the related preferred embodiments of these steps can also refer to the corresponding related descriptions, which are not repeated here.

In some embodiments, FPGA can be used as a verification chip to form a multi-FPGA prototype verification system, which is very convenient for chip design segmentation verification and can improve the correctness and efficiency of verification.

In practice, the verification chip may include an FPGA chip: Accordingly, the verification system may include a multi-FPGA prototype verification system.

Based on the same inventive concept, the embodiment of the specification also provides a device, an electronic device and a computer storage medium corresponding to the verification method.

As shown in FIG. 15, an embodiment of this specification provides a verification apparatus 700, which may include a classification module 701, which classifies the nodes in the chip design to correspondingly divide each node into nodes with ffd attributes, nodes with inherited ffd attributes or nodes without ffd attributes: A merging module 703, which merges nodes without ffd attributes with nodes with ffd attributes or nodes with inherited ffd attributes according to a preset merging strategy to form a target graph: A segmentation module 705, which segments the target graph according to a preset segmentation strategy, so as to set the segmentation boundary on the output line of the node with ffd attribute in the target graph, or set the segmentation boundary on the output line of the node with ffd attribute inherited in the target graph: The verification module 707 uses a verification system to verify the segmentation result, wherein the verification system includes at least two verification chips.

Based on the same inventive concept, the embodiment of this specification also provides an electronic device for verification, so as to realize the verification scheme corresponding to any of the aforementioned embodiments.

It should be noted that the electronic device may include: at least one processor; And a memory communicatively connected with the at least one processor: Wherein, the memory stores instructions executable by the at least one processor, and the instructions are executed by the at least one processor, so that the at least one processor can execute the verification method described in any of the aforementioned embodiments. For details, please refer to the description of the aforementioned embodiment of the electronic device for segmentation, which will not be described here.

Based on the same inventive concept, the embodiment of this specification also provides a computer storage medium for verification, wherein the computer storage medium stores computer executable instructions, and the computer executable instructions are set as: instructions for implementing the verification method corresponding to any of the aforementioned embodiments.

It should be noted that the description of the computer storage medium can refer to the description of the previous embodiment, and will not be described here.

Each embodiment in this specification is described in a progressive way, and only the same and similar parts between the embodiments can be referred to each other, and each embodiment focuses on the differences from other embodiments. Especially, for the product embodiment described later, because it corresponds to the method, the description is relatively simple, and the relevant points can only be found in part of the description of the method embodiment.

In this specification, each embodiment can be an entirely hardware embodiment, an entirely software embodiment or an embodiment implemented in combination of software and hardware.

The above is only the specific implementation of this application, but the protection scope of this application is not limited to this. Any change or replacement that can be easily thought of by a person familiar with this technical field within the technical scope disclosed in this application should be covered by this application. Therefore, the protection scope of this application should be based on the protection scope of the claims.

1. A segmentation method, characterized in that, including:
classifying the nodes in the chip design, so as to divide each node into: nodes with ffd attributes, nodes with inherited ffd attributes or nodes without ffd attributes;
merging nodes without ffd attributes with nodes with ffd attributes or nodes with inherited ffd attributes according to a preset merging strategy to form a target graph;
segmenting the target graph according to a preset segmentation strategy, so as to set the segmentation boundary on the output line of the node with ffd attribute in the target graph, or set the segmentation boundary on the output line of the node with ffd attribute inherited in the target graph.

2. The segmentation method according to claim 1, characterized in that before classifying the nodes in the chip design, the segmentation method further includes:
reading a design file corresponding to the chip design;
generating classification information corresponding to each node according to the design file, wherein the classification information includes node attribute information, and the node attribute information includes attribute information representing whether a node has an ffd attribute;
classifying the nodes in the chip design, including: classifying the nodes in the chip design according to the classification information.

3. The segmentation method according to claim 2, characterized in that the classification information further comprises at least one of the following information:
the original design module name information corresponding to each node, the network connection information between nodes and the preset segmentation standard information;
and/or the node attribute information further includes resource occupation information representing the number of resources occupied by each node.

4. The segmentation method according to claim 1, characterized in that the preset segmentation strategy includes: a segmentation strategy for segmentation by weight:
the segmentation method further includes:
according to the preset weight adjustment strategy, the weight of the target connection line is adjusted, wherein the driving node of the target connection line belongs to a node with ffd attribute or a node with inherited ffd attribute.

5. The segmentation method according to claim 4, characterized in that after segmenting the target graph according to a preset segmentation strategy, the segmentation method further includes:
checking the segmentation result to determine whether the segmentation boundary cuts the target connection line.

6. The segmentation method according to claim 5, characterized in that when determining a segmentation boundary to cut the target connection line, the segmentation method further includes:
determining whether the first driving node is the node that really obtains the ffd attribute, wherein the first driving node is the driving node of the target connection line.

7. The segmentation method according to claim 6, characterized in that determining whether the first driving node is the node that really obtains the ffd attribute includes:
determining whether a connecting line between a first driving node and a second driving node is cut, wherein the second driving node is the driving node of the first driving node;
If yes, it is determined that the first driving node does not belong to the node that really obtains the ffd attribute.

8. The segmentation method according to claim 7, characterized in that, after determining that the first driving node does not belong to the node that truly obtains the ffd attribute, the segmentation method further includes:
merging the first driving node and the second driving node to divide the first driving node and the second driving node into the same verification chip.

9. The segmentation method according to claim 8, characterized in that in merging the first driving node and the second driving node, the segmentation method further includes:
determining the merging of the first driving node and the second driving node generates a new target connection line.

10. The segmentation method according to claim 9, characterized in that when it is determined that a new target connection is generated, the segmentation method further includes: outputting prompt information, wherein the prompt information is used to characterize that the new target connection belongs to an illegal connection line.

11. The segmentation method according to claim 1, characterized in that before segmenting the target graph, the segmentation method further includes clustering the nodes in the target graph according to a preset clustering strategy.

12. The segmentation method according to claim 11, characterized in that the segmentation method further comprises:
restoring the clustered nodes;
adjust the restored nodes to another partition to reduce the number of cut lines and make the drive nodes of the cut lines have ffd attributes.

13. A verification method, including:
classifying the nodes in the chip design, so as to divide each node into: nodes with ffd attributes, nodes with inherited ffd attributes or nodes without ffd attributes;
merging nodes without ffd attributes with nodes with ffd attributes or nodes with inherited ffd attributes according to a preset merging strategy to form a target graph;
segmenting the target graph according to a preset segmentation strategy, so as to set the segmentation boundary on the output line of a node with ffd attribute in the target graph, or set the segmentation boundary on the output line of a node with ffd attribute inherited in the target graph;
a verification system is adopted to verify the segmentation result, wherein the verification system at least comprises two verification chips.

14. The verification method according to claim 13, characterized in that, wherein the verification chip comprises an FPGA chip, and the verification system comprises a multi-FPGA prototype verification system.

15. A segmentation apparatus, characterized in that including:
a classification module is used for classifying the nodes in the chip design so as to correspondingly divide each node into nodes with ffd attributes, nodes with inherited ffd attributes or nodes without ffd attributes;
a merging module, which merges nodes without ffd attributes with nodes with ffd attributes or nodes with inherited ffd attributes according to a preset merging strategy to form a target graph;
a segmentation module is used for segmenting the target graph according to a preset segmentation strategy, so as to set the segmentation boundary on the output line of the node with ffd attribute in the target graph, or set the segmentation boundary on the output line of the node with ffd attribute inherited in the target graph.

16. A verification apparatus, characterized in that including:
a classification module is used for classifying the nodes in the chip design so as to correspondingly divide each node into nodes with ffd attributes, nodes with inherited ffd attributes or nodes without ffd attributes;
a merging module, which merges nodes without ffd attributes with nodes with ffd attributes or nodes with inherited ffd attributes according to a preset merging strategy to form a target graph;
a segmentation module is used for segmenting the target graph according to a preset segmentation strategy, so as to set the segmentation boundary on the output line of a node with ffd attribute in the target graph, or set the segmentation boundary on the output line of a node with ffd attribute inherited in the target graph;
a verification module is used for verifying the segmentation result by adopting a verification system, wherein the verification system at least comprises two verification chips.

17. An electronic device for segmentation, characterized in that including:
at least one processor; and a memory communicatively connected with the at least one processor: wherein the memory stores instructions executable by the at least one processor, and the instructions are executed by the at least one processor to enable the at least one processor to execute:
classifying the nodes in the chip design, so as to divide each node into nodes with ffd attributes, nodes with inherited ffd attributes or nodes without ffd attributes;
merging nodes without ffd attributes with nodes with ffd attributes or nodes with inherited ffd attributes according to a preset merging strategy to form a target graph;
segmenting the target graph according to a preset segmentation strategy, so as to set the segmentation boundary on the output line of the node with ffd attribute in the target graph, or set the segmentation boundary on the output line of the node with ffd attribute inherited in the target graph.

18. An electronic for verification, characterized in that including:
at least one processor; and a memory communicatively connected with the at least one processor: wherein the memory stores instructions executable by the at least one processor, and the instructions are executed by the at least one processor to enable the at least one processor to execute:
classifying the nodes in the chip design, so as to divide each node into nodes with ffd attributes, nodes with inherited ffd attributes or nodes without ffd attributes;
merging nodes without ffd attributes with nodes with ffd attributes or nodes with inherited ffd attributes according to a preset merging strategy to form a target graph;
segmenting the target graph according to a preset segmentation strategy, so as to set the segmentation boundary on the output line of a node with ffd attribute in the target graph, or set the segmentation boundary on the output line of a node with ffd attribute inherited in the target graph;
a verification system is adopted to verify the segmentation result, wherein the verification system at least comprises two verification chips.

19. A computer storage medium for segmentation, wherein the computer storage medium stores computer executable instructions, and the computer executable instructions are set to:
classifying the nodes in the chip design, so as to divide each node into nodes with ffd attributes, nodes with inherited ffd attributes or nodes without ffd attributes;
merging nodes without ffd attributes with nodes with ffd attributes or nodes with inherited ffd attributes according to a preset merging strategy to form a target graph;
segmenting the target graph according to a preset segmentation strategy, so as to set the segmentation boundary on the output line of the node with ffd attribute in the target graph, or set the segmentation boundary on the output line of the node with ffd attribute inherited in the target graph.

20. A computer storage medium for verification, characterized in that the computer storage medium stores computer executable instructions, and the computer executable instructions are set to:
classifying the nodes in the chip design, so as to divide each node into nodes with ffd attributes, nodes with inherited ffd attributes or nodes without ffd attributes;
merging nodes without ffd attributes with nodes with ffd attributes or nodes with inherited ffd attributes according to a preset merging strategy to form a target graph;
segmenting the target graph according to a preset segmentation strategy, so as to set the segmentation boundary on the output line of a node with ffd attribute in the target graph, or set the segmentation boundary on the output line of a node with ffd attribute inherited in the target graph;
a verification system is adopted to verify the segmentation result, wherein the verification system at least comprises two verification chips.
